(19) United States
(12) Patent Application Publication
(10) Pub. No.: US 2020/0119504 A1
(43) Pub. Date: Apr. 16, 2020

(54) Relay Adapter And Relay Adapter Containing Connector System

(71) Applicant: Tyco Electronics Japan G.K., Kawasaki (JP)

(72) Inventor: Takafumi Kubo, Kawasaki-shi (JP)

(73) Assignee: Tyco Electronics Japan G.K., Kawasaki (JP)

(21) Appl. No.: 16/599,200

(22) Filed: Oct. 11, 2019

(30) Foreign Application Priority Data
Oct. 12, 2018 (JP) 2018-193092

(51) Int. Cl. H01R 31/06; H01R 13/52; H05K 1/11

(52) U.S. Cl. CPC H01R 31/06; H01R 12/72; H05K 1/117; H01R 13/5219

(57) ABSTRACT

A relay adapter includes a first mating portion matable with a first connector positioned in an equipment enclosure, a second mating portion matable with a second connector, and a seal portion positioned between the first mating portion and the second mating portion. The second mating portion forms a watertight connection with the second connector. The seal portion forms a watertight connection with the equipment enclosure.

### CROSS-REFERENCE TO RELATED APPLICATION

This application claims the benefit of the filing date under 35 U.S.C. § 119(a)-(d) of Japanese Patent Application No. 2018-193092, filed on Oct. 12, 2018.

### FIELD OF THE INVENTION

The present invention relates to a connector system and, more particularly, to a relay adapter of a connector system.

### BACKGROUND

In a piece of electronic equipment, such as a smartphone, a built-in connector is positioned inside a hole provided in an enclosure of the electronic equipment. A waterproof structure covers an inlet of the hole with a waterproof lid. However, waterproofness is not ensured when the lid is opened; waterproofness is not maintained when an external connector is plugged in the built-in connector.

In a conventional built-in connector, waterproofness when the external connector is plugged in the built-in connector is ensured by modifying parts other than the built-in connector. In many cases, a cable is often connected to the external connector. An unintentional force may be applied to the cable. Therefore, even if waterproofness when the external connector is plugged therein is ensured, the unintentional force may cause the external connector to be unplugged, which may result in water ingress into the equipment.

Alternatively, changing the built-in connector into a connector suitable for water ingress prevention is also conceivable. However, in that case, an external connector that mates with the conventional type of built-in connector may no longer be available. Japanese Patent No. H11-121102A, for example, discloses a waterproof connector made by adding an adapter, a cover, and a seal member fixedly to a non-waterproof connector. The disclosed waterproof connector has a component added for outdoor installation, but is not suitable for use with the external connector that mates with the conventional type of built-in connector.

### SUMMARY

A relay adapter includes a first mating portion matable with a first connector positioned in an equipment enclosure, a second mating portion matable with a second connector, and a seal portion positioned between the first mating portion and the second mating portion. The second mating portion forms a watertight connection with the second connector. The seal portion forms a watertight connection with the equipment enclosure.

### BRIEF DESCRIPTION OF THE DRAWINGS

The invention will now be described by way of example with reference to the accompanying Figures, of which:

FIG. 1 is a perspective view of a relay adapter according to an embodiment;

FIG. 2 is a sectional perspective view of the relay adapter of FIG. 1;

FIG. 3 is an exploded perspective view of a connector system including the relay adapter of FIG. 1; and

FIG. 4 is an exploded perspective view of a connector system according to another embodiment including a relay adapter according to another embodiment.

### DETAILED DESCRIPTION OF THE EMBODIMENT(S)

Exemplary embodiments of the present disclosure will be described hereinafter in detail with reference to the attached drawings, wherein like reference numerals refer to like elements. The present disclosure may, however, be embodied in many different forms and should not be construed as being limited to the embodiment set forth herein; rather, these embodiments are provided so that the present disclosure will fully convey the concept of the disclosure to those skilled in the art.

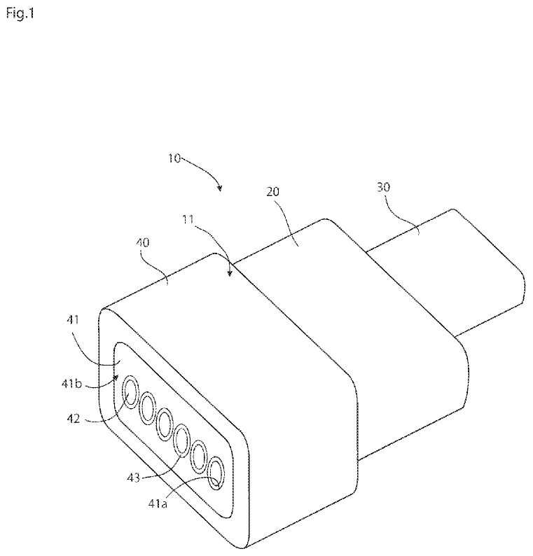

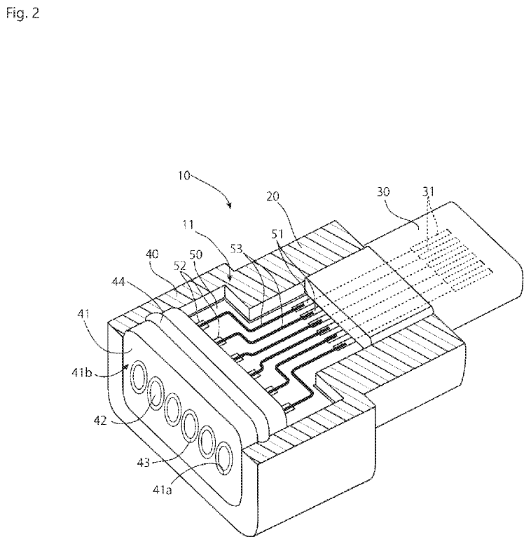

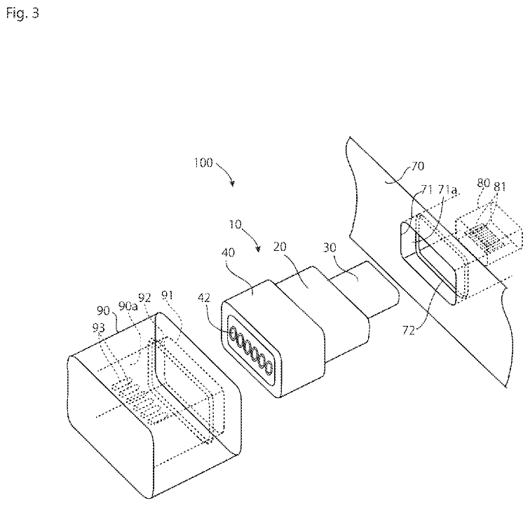

A relay adapter 10 according to an embodiment, shown in FIGS. 1 and 2, has a seal portion 20 in a middle thereof, a first mating portion 30 on a first end adjoining the seal portion 20, and a second mating portion 40 on a second end opposite the first end. The first mating portion 30 mates with a first connector 80 provided in an equipment enclosure 70, shown in FIG. 3. The second mating portion 40 mates with a second connector 90, shown in FIG. 3.

As shown in FIG. 1, the second mating portion 40 has a pad retaining portion 41 surrounded by a housing 11. A plurality of holes 41a are arranged in the pad retaining portion 41. One of a plurality of pads 42 having a flat rear face is fitted in each of these holes 41a as to be exposed on a rear face 41b of the pad retaining portion 41. A seal member 43 seals in a watertight manner between an inner wall face of each hole 41a and each pad 42.

As shown in FIG. 2, a pad O-ring 44 is positioned on an outer wall face of the pad retaining portion 41 to form a waterproof structure between the pad retaining portion 41 and the housing 11.

As shown in FIG. 2, a plurality of adapter-side contacts 31 are arranged in the first mating portion 30. The first mating portion 30 has a same shape as a conventional external connector that mates with the first connector 80.

A circuit board 50 is disposed in the housing 11, as shown in FIG. 2, in a position extending into the seal portion 20 and the second mating portion 40. A plurality of first contact portions 51 are arranged on a side of the first mating portion 30 of the circuit board 50. The arrangement pitch of the first contact portions 51 is the same pitch as a first pitch of the adapter-side contacts 31 provided in the first mating portion 30. The first contact portions 51 are each connected to one of the corresponding adapter-side contacts 31.

A plurality of second contact portions 52, shown in FIG. 2, are arranged on a side of the second mating portion 40 of the circuit board 50. The arrangement pitch of the second contact portions 52 is the same pitch as a second pitch of the pads 42 provided in the second mating portion 40. The second contact portions 52 are each connected to one of the corresponding pads 42. The arrangement pitch of the second contact portions 52 and the pads 42 is a larger pitch than the arrangement pitch of the first contact portions 51 and the adapter-side contacts 31. The first contact portions 51 and the second contact portions 52 are paired with each other and interconnected via wires 53 on the circuit board 50. The circuit board 50 is an example of a pitch converting portion.

A connector system 100 according to an embodiment, shown in FIG. 3, includes the relay adapter 10 shown in FIG. 1, the first connector 80 shown on a side of the first mating portion 30 of the relay adapter 10, and the second connector 90 shown on a side of the second mating portion 40.

The first connector 80, as shown in FIG. 3, is built in the equipment enclosure 70. A hole 71 is provided in the equipment enclosure 70. The hole 71 has dimensions corresponding to the outer dimensions of the seal portion 20 of the relay adapter 10. The relay adapter 10 is plugged into the hole 71 from the first mating portion 30 to the seal portion 20. Once the first mating portion 30 and the seal portion 20 are plugged into the hole 71, the first mating portion 30 mates with the first connector 80. The adapter-side contacts 31 provided in the first mating portion 30 are electrically connected to a plurality of first contacts 81 provided in the first connector 80. In a portion of the hole 71 into which the seal portion 20 is plugged, a first O-ring 72 is positioned along an inner wall face 71a of the hole 71. The first O-ring 72 prevents water ingress between the inner wall face 71a of the hole 71 and an outer wall face of the seal portion 20. The seal portion 20 forms a watertight connection with the equipment enclosure 70.

The second mating portion 40 of the relay adapter 10, as shown in FIG. 3, is fitted into a mating opening 91 of the second connector 90. A second O-ring 92 is positioned inside the mating opening 91. The second O-ring 92 prevents water ingress between an inner wall face 90a contiguous to the mating opening 91 and an outer wall face of the second mating portion 40 of the relay adapter 10. The second mating portion 40 forms a watertight connection with the second connector 90.

As shown in FIG. 3, a plurality of pin-shaped second contacts 93 are arranged in the second connector 90. The second contacts 93 are urged by spring members in a projecting direction toward the mating opening 91. In an embodiment, the second contacts 93 are each a pogo pin. When the second mating portion 40 of the relay adapter 10 is fitted into the mating opening 91 of the second connector 90, each second contact 93 abuts against each pad 42 with an adequate pressing force, and thus each pad 42 and each second contact 93 are electrically connected together.

Using the relay adapter 10 and the second connector 90 enables communication between the inside and outside of the equipment while preventing water ingress into the equipment enclosure 70. In addition, for a user who does not particularly need to prevent water ingress, or in a situation that does not need to prevent water ingress, it is not necessary to use the relay adapter 10 or the second connector 90. In that case, communication is enabled by omitting the relay adapter 10 and using a conventional connector mating with the first connector 80.

The seal portion 20 of the relay adapter 10 is relatively strongly plugged into the hole 71 of the equipment enclosure 70. In contrast, the second mating portion 40 of the relay adapter 10 is fitted into the second connector 90 with a relatively weak force as compared with when the seal portion 20 is plugged into the hole 71. A cable is connected to the second connector 90. If an unintentional force is applied to the cable, the second mating portion 40 and the second connector 90 are unmated with a weaker force than when the relay adapter 10 is unplugged from the hole 71. Therefore, even if such an unintentional force acts, water ingress into the equipment enclosure 70 is prevented. In another embodiment, a mechanism for locking the relay adapter 10 plugged in the hole 71 to the equipment enclosure 70 may be provided. This further reliably prevents the relay adapter 10 from being unplugged from the hole 71 when an unintentional force is applied.

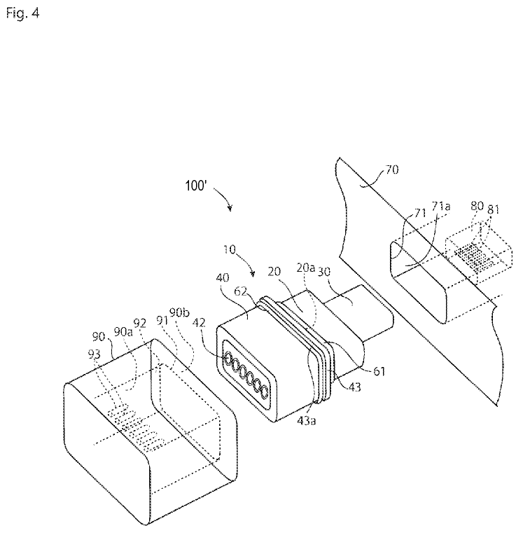

A connector system 100′ according to another embodiment is shown in FIG. 4. In FIG. 4, an element corresponding to each element of the first embodiment shown in FIG. 3 is denoted by the same reference numeral as used in FIG. 3, and thus only a difference will be described.

In the connector system 100′ shown in FIG. 4, the first O-ring 72 is not provided in the equipment enclosure 70. In addition, similarly, the second O-ring 92 is not provided in the second connector 90, either. In the connector system 100′, a first O-ring 61 is positioned in the vicinity of a wall face 20a on the boundary with the second mating portion 40 of the seal portion 20. The second mating portion 40 has a flange portion 43 projecting in an circumferential manner, and a second O-ring 62 is positioned in the vicinity of a wall face 43a on a side of the second connector 90 of the flange portion 43.

The relay adapter 10 is plugged into the hole 71 of the equipment enclosure 70. Thereupon, the first O-ring 61 shown in FIG. 4 is held in a circumferential manner between an outer peripheral face of the seal portion 20 and the inner peripheral face 71a of the hole 71 of the equipment enclosure 70. Thereby, waterproofness of the equipment enclosure 70 is ensured.

In addition, the second mating portion 40 of the relay adapter 10 is plugged into the mating opening 91 of the second connector 90. Thereupon, in the same manner as described above, the second O-ring 62 shown in FIG. 4 positioned on the side of the second connector 90 of the flange portion 43 is held in a circumferential manner between an outer peripheral face of the second mating portion 40 and the inner wall face 90a of the second connector 90. Thereby, waterproofness between the relay connector 10 and the second connector 90 is ensured.

As shown in FIGS. 3 and 4, the waterproof structure may be provided in the relay adapter 10 or may be provided in the equipment enclosure 70 and/or the second connector 90.

What is claimed is:

1. A relay adapter, comprising:
a first mating portion pluggable into a hole in an equipment enclosure and matable with a first connector positioned in the equipment enclosure, the first mating portion having an adapter-side contact electrically connected to a first contact of the first connector;
a seal portion positioned behind the first mating portion in a plugging direction toward the hole and preventing water ingress between the relay adapter and the equipment enclosure; and
a second mating portion matable with a second connector and preventing water ingress between the relay adapter and the second connector, the second mating portion having a pad electrically connected to the adapter-side contact, the pad abutting a second contact of the second connector and electrically connected with the second contact.

2. The relay adapter of claim 1, wherein the first mating portion has a plurality of adapter-side contacts arranged at a first pitch.

3. The relay adapter of claim 2, wherein the second mating portion has a plurality of pads arranged at a second pitch.

4. The relay adapter of claim 3, wherein the second pitch is larger than the first pitch.

5. The relay adapter of claim 4, further comprising a pitch converting portion electrically connected between the adapter-side contacts and the pads.

6. A connector system, comprising:
a first connector having a first contact, the first connector is positioned in an equipment enclosure with a hole;
a second connector having a second contact; and
a relay adapter having a first mating portion pluggable into the hole and matable with the first connector, the first mating portion having an adapter-side contact electrically connected to the first contact, a seal portion positioned behind the first mating portion in a plugging direction toward the hole and preventing water ingress between the relay adapter and the equipment enclosure, and a second mating portion matable with the second connector and preventing water ingress between the relay adapter and the second connector, the second mating portion having a pad electrically connected to the adapter-side contact, the pad abutting the second contact of the second connector and electrically connected with the second contact.

7. A relay adapter, comprising:
a first mating portion matable with a first connector positioned in an equipment enclosure;
a second mating portion matable with a second connector and forming a watertight connection with the second connector; and
a seal portion positioned between the first mating portion and the second mating portion, the seal portion forming a watertight connection with the equipment enclosure.

8. The relay adapter of claim 7, wherein the first mating portion is plugged into a hole of the equipment enclosure, a first O-ring is positioned between an inner wall face of the hole and an outer wall face of the seal portion.

9. The relay adapter of claim 8, wherein the second mating portion is plugged into a mating opening of the second connector, a second O-ring is positioned between an inner wall face of the mating opening and an outer wall face of the second mating portion.

10. The relay adapter of claim 9, wherein the first O-ring is disposed in the equipment enclosure and the second O-ring is disposed in the mating opening.

11. The relay adapter of claim 9, wherein the first O-ring is positioned at a wall face a boundary between the second mating portion and the seal portion.

12. The relay adapter of claim 11, wherein the second mating portion has a flange portion projecting in a circumferential manner.

13. The relay adapter of claim 12, wherein the second O-ring is positioned on a side of the flange portion facing the second connector.

14. The relay adapter of claim 7, wherein the first mating portion has an adapter-side contact electrically connected to a first contact of the first connector.

15. The relay adapter of claim 14, wherein the second mating portion has a pad electrically connected to the adapter-side contact.

16. The relay adapter of claim 15, wherein the pad is electrically connected with a second contact of the second connector.

17. The relay adapter of claim 16, wherein the second mating portion has a pad retaining portion surrounded by a housing.

18. The relay adapter of claim 17, wherein the pad retaining portion has a hole in which the pad is disposed.

19. The relay adapter of claim 18, wherein the second mating portion has a seal member is disposed between an inner wall face of the hole and the pad.

20. The relay adapter of claim 17, wherein the second mating portion has a pad O-ring disposed between an outer wall face of the pad retaining portion and the housing.
